(19) United States
(12) Patent Application Publication
(10) Pub. No.: US 2020/0116798 A1
(43) Pub. Date: Apr. 16, 2020

(54) BATTERY OPERATED LEVEL MEASURING DEVICE WITH REMAINING LIFE DETERMINATION DEVICE

(71) Applicant: VEGA GRIESHABER KG, Wolfach (DE)

(72) Inventors: Roland WELLE, Hausach (DE); Joerg Boersig, Schapbach (DE); Steffen Waelde, Niedereschach (DE)

(73) Assignee: VEGA GRIESHABER KG, Wolfach (DE)

(21) Appl. No.: 16/599,711

(22) Filed: Oct. 11, 2019

(30) Foreign Application Priority Data
Oct. 11, 2018 (EP) 18 199 933.5

(51) Int. Cl. G01R 31/392; G01R 31/36; G01R 31/3835

(52) U.S. Cl. CPC G01R 31/392; G01R 31/3835; G01R 31/3648

(57) ABSTRACT

A battery operated level measuring device with a remaining life determination device which provides information from which a minimum value of the remaining battery life can be calculated. This calculation of the remaining battery life can be done in the measuring device or cloud.

### CROSS-REFERENCE TO RELATED APPLICATIONS

This application claims the benefit of the filing date of European Patent Application No. 18 199 931.5 filed on 11 Oct. 2018, the entire contents of which are incorporated herein by reference.

### FIELD

The disclosure relates to level measurement technology. In particular, the disclosure relates to a battery operated level measuring device, a method for determining the remaining life of a battery of a measuring device, and a computer-readable medium.

### BACKGROUND

Most level measuring devices are supplied with energy via cables. The measurement data is also sent to a remote control station via cable. The wiring effort is sometimes considerable and restricts the range of application of the measuring devices.

### SUMMARY

It is an object of the disclosure to increase the application range of level measuring devices.

This object is solved by the features of the present claims. Further embodiments follow from the dependent claims and the following description of the embodiments.

A first aspect relates to a battery operated level measuring device with a battery and a remaining life determination device, which fur example has a processor and one or more measuring circuits or measuring devices. The remaining life determination device is arranged to provide information from which a minimum value of the remaining battery life can be calculated.

For example, the device may be configured to determine the minimum value of battery life from the age or operating hours of the battery and with knowledge of the measurement operation of the level measuring device. If the remaining life determination device knows the energy requirement of the level measuring device required per measurement as well as the time interval between future measurements, a minimum value for the remaining battery life can be calculated, especially if the current state of charge of the battery is known.

According to an embodiment, other information that the remaining life determination device can obtain can also be included in the determination of this minimum value. Examples of this are the actual amount of charge removed from the battery, the current battery voltage, the current temperature of the battery or the measuring device, the current date and time, if applicable, the previous number of measurements, the planned time interval for future measurements, the previous number of (radio) transmissions of measured values, the planned time interval for radio transmissions, the ambient temperature, the previous number of measured value displays or the previous duration of measured value displays, the planned time interval of measured value displays, the planned measured value display time, the previous calculation effort of the measuring device and the planned future calculation effort.

The level measuring device can be set up to calculate the minimum value itself Alternatively, the part of the remaining life determination device installed in the measuring device ma provide the required information and then transmit it via a wireless interface (radio module) to an externally arranged part of the remaining life determination device. This can be, for example, a cloud or an external server that then performs the calculations.

According to an embodiment, the measuring device, server or cloud may be required to take action if the battery Charge level falls below a certain threshold, or if the calculated minimum remaining battery life falls below a certain threshold, or if the number of measurements that can still be performed (before the battery is depleted) falls below a certain threshold.

In this way, the battery life can be extended and it can be prevented that the battery is completely drained. For example, the distance between successive measurement cycles can be increased. It is also possible to avoid further radio transmissions or to increase the distance between successive radio transmissions. It is also possible to reduce the measuring accuracy in this case in order to save energy per measuring cycle.

It can also be provided that the server or the cloud intervenes in time in the measuring process and changes the parameterization of the measuring device in order to save energy so that the battery does not run out.

According to one embodiment, this function is programmed into the measuring device so that no external control is required to prevent the battery from running out. In particular, the device may be set to fall into a sleep mode when the battery charge condition allows only a small number of measurements to be made. This sleep mode is only exited when requested externally, e.g. by the user. Then the measuring device wakes up and carries out a last measurement and radio transmission.

According to another embodiment of the invention, the remaining life determination device has a counting unit that is set up to count the measurements performed by the level measuring device.

According to another embodiment of the invention, the counting unit is set up to count the number of measured value display events and/or measured value transmissions to an external receiver.

According to another embodiment of the invention, the remaining life determination device has a Coulomb meter which is configured to measure the amount of charge removed from the battery.

According to another embodiment of the invention, the Coulomb meter is integrated into a battery voltage control unit of the level measuring device.

According to another embodiment of the invention, the remaining life determination device has a battery voltage control unit which is arranged to measure the voltage of the battery.

According to another embodiment of the invention, the remaining life determination device has a temperature sensor which is arranged to measure the temperature of the battery.

According to a further embodiment of the invention, the remaining life determination device has a real time clock which is configured to determine the current date and/or the current time and to compare it with a time stamp of the battery which, for example, is stored in the measuring device at the factory.

According to another embodiment of the invention, the battery operated level measuring device has a data memory in which information about the type and capacity of the battery used is stored.

According to a further embodiment of the invention, the remaining life determination device is arranged to include the number of measurements performed by the level measuring device, the number of measured value display events and/or measured value transmissions to the external receiver, the amount of charge taken from the battery, the voltage of the battery and/or the current date, the current time and/or the information on the type and capacity of the ‘battery in the information provided or to take it into account when calculating the minimum value of the remaining battery life.

According to another embodiment of the invention, the battery is fixed in the level measuring device so that it cannot be replaced.

According to another embodiment of the invention, the level measuring device is exclusively battery operated.

In particular, it may be intended that the battery and/or all components of the level measuring device are enclosed in a housing which cannot be opened. For example, the components may be encapsulated in the housing. This can ensure very effective explosion protection and/or chemical protection.

Another aspect relates to a method for determining a remaining battery life of a measuring device, which provides information from which a minimum value of the remaining battery life can be calculated. This is done by a remaining life determination device on the measuring device. Then a minimum value of the remaining battery life is calculated from this information, either by the remaining life determination device integrated in the device or by an external evaluation device.

Another aspect is a program element that, when run on a processor or calculation circuit of a measuring device, instructs the measuring device to perform the steps described above and below.

Another aspect relates to a computer-readable medium an which the program element described above is stored.

The following is a description of the invention's embodiments with reference to the figures. The illustrations in the figures are schematic and not to scale. If the same reference signs are used in the figures, these designate the same or similar elements.

### BRIEF DESCRIPTION OF THE DRAWINGS

FIG. 1 shows a level measuring system with a battery level measuring device.

FIG. 2 shows another level measuring system with a battery operated level measuring device.

FIG. 3 shows a flow chart of a method.

### DETAILED DESCRIPTION OF THE EMBODIMENTS

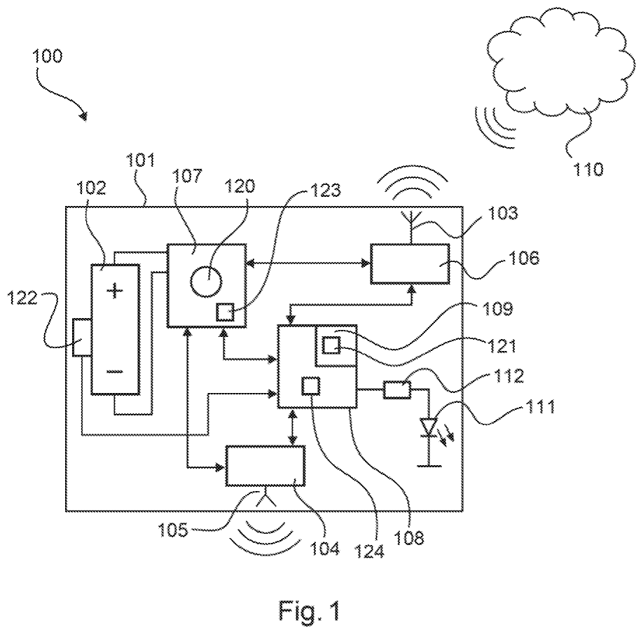

FIG. 1 shows a measuring system with a measuring device 100, for example in the form of a level measuring device. The measuring device 100 can in particular be a radar level device, but also, for example, a limit level sensor or a pressure measuring device. However, it can also be another battery operated measuring device.

In particular, the measuring device can be wireless, so that it can be used without cabling. For example, it can be mounted directly on or in a mobile container.

The battery operated level measuring device can be used flexibly and has a radio module with a corresponding radio standard for reading the measurement data. The duty cycle, i.e. the ratio of the length of the measurement and measurement data transmission to the measurement pause, is a decisive factor for the duration during which the level measuring device can be used without changing the battery.

If this ratio becomes very high, i.e. the measuring pauses become very long, measures can be taken in the energy management of the measuring device circuit to anther save energy. Software routines, components and component circuits from the ultra-low power segment can be used for this purpose. In order to increase user-friendliness and avoid measurement failures, the expected remaining battery life can be calculated and output.

In order to make the level measuring device suitable for use in potentially explosive atmospheres and to facilitate its approval, the battery or rechargeable battery of the level measuring device may not be replaceable.

Additional mounting brackets, which are required for wireless devices with exchangeable energy storage, are not necessary. Furthermore, no housing openings are required, which further reduces the manufacturing effort of the measuring device.

Since no openings in the housing wall are necessary and, in particular, it is possible that the battery and the electronic circuit are enclosed with a sealing compound, the use of the device in potentially explosive atmospheres can be facilitated.

The measuring device has a radio module 106 with an antenna 103. This may be a GSM, Win, LoRa or Sigfox module. Preferably, a radio standard is used which requires as little energy as possible for the transmission of the measured values.

The level measuring device is particularly suitable for mounting on mobile containers which, for example, change location for emptying or filling. For this purpose, it is important that the operator of the system receives information about the state of charge of the battery. One reason for this is that if the sensor no longer responds, the operator cannot tell whether the sensor is no longer within range of his radio network or whether the battery is empty.

Determining the state of charge of the battery 102, for example a lithium ion battery, is demanding. Various effects can affect the remaining capacity of a battery. These include age of the battery, ambient temperature, possible damage to the outer shell and associated oxidation, as well as the number, duration and frequency of current peaks occurring during the operating phase. In addition, these effects vary depending on the type and design of the measuring device and battery.

The remaining life determination device 109 can determine the remaining life of the installed battery 102 using various methods. The remaining life determination device 109 can use data from integrated sensors 120, 121, 122, 123, 124 (e.g. measurement circuitry).

For example, the remaining life determination device 109 can receive information from a Coulomb meter 120, which measures the amount of charge removed from the battery 102. The Coulomb meter can be integrated into the battery voltage control unit 107.

Alternatively or additionally, the battery voltage can be measured via the battery voltage control writ 107, which can also provide information about the current state of charge of the battery.

Further sensors can be provided for a more precise determination of the minimum value of the remaining battery life. For example, the current temperature can be read out via a temperature sensor or temperature sensor 122. The temperature sensor can be integrated in the components 107, 106, 108 or 104 or be an independent component, which for example is mounted directly in the area of the battery 102.

In addition, the current date can be determined via a real time clock 123 and compared with a time stamp stored in the factory-preset system in order to determine the age of the battery 102. The real time clock 123 can be integrated into the battery voltage control unit 107 or the part 109 of the remaining life determination device integrated in the processor of the measuring device.

In addition, information on how often a measured value has already been recorded, evaluated and displayed via the sensor unit 104 or sent via the radio module 106 can be helpful in determining the remaining battery life. The sensor unit 104 can, for example, work according to the radar principle, for which a radar antenna 105 is provided to radiate and receive the measurement signal. For this purpose, it must he known how much current a measurement cycle requires, including measurement data evaluation and transmission if necessary. In particular, it should be known how much current flows while the radio module is sending and receiving data. The current characteristic values of these and other circuit components (e.g. real-time clock, LEDs, . . . ) can already be determined at the factory and stored in a memory 124.

Further information that can already be stored in the memory at the factory is the type and capacity of the battery on which the calculation of the remaining battery life also depends. In addition, a worst-case analysis can be made at the factory for different battery types, which provides a value for the minimum remaining battery life in the worst case. This time can also be stored in the memory.

Another important point to consider is the parameterization of the sensor. This can be designed in such a way that a parameterization can be used to set how often the sensor (i.e. the measuring device) performs a measurement and when and whether it transmits the determined measured value via the radio module 106. The information about the parameterization is important if the remaining battery life is to be specified in a time unit (days, hours, minutes, . . . ).

In contrast, the remaining battery life can also be specified in measurement cycles.

On the basis of this and other possible data and additional empirical values, the remaining battery life of the level measuring device 100 can be estimated.

The calculations that the remaining life determination device 109 has to perform for determining the remaining battery life can be performed in one form on the central control and computing unit (processor) 108 (e.g. a microcontroller or processing circuitry).

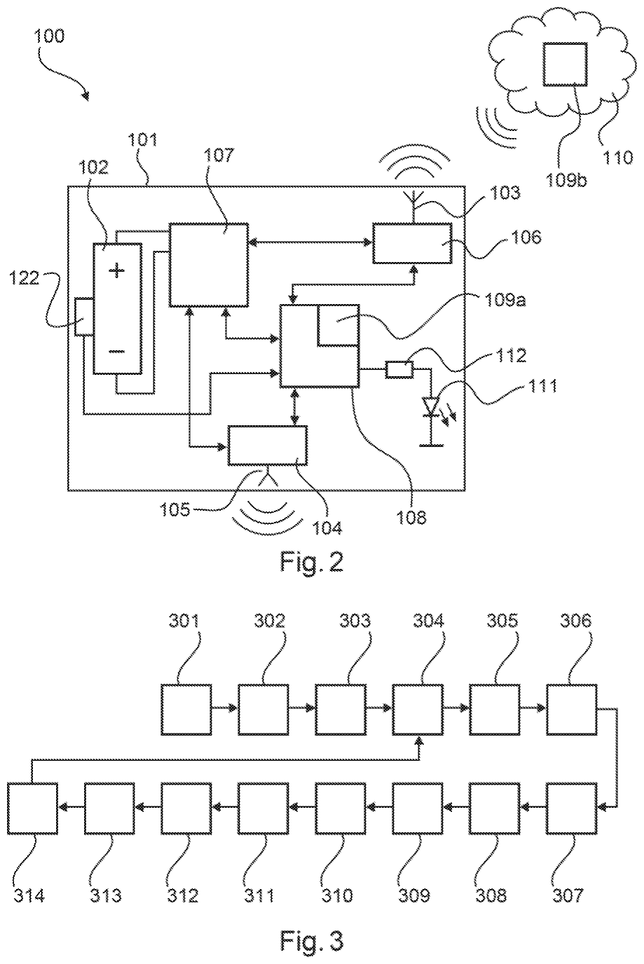

In a further embodiment, the data determined by the remaining life determination device 109a (see FIG. 2) are sent unprocessed via, the radio module to a Cloud 110 or an external server, where the calculations for determining the remaining battery life (minimum value) are performed by a virtual remaining life determination device 109b.

In the Cloud 110, the user of the level measuring device 100 can also be informed, for example, how many measuring cycles are still to be expected from the battery operated level measuring device 100 and, if necessary, a warning message is issued in the event of a critical remaining time.

Furthermore, the remaining battery life calculated in the cloud can be sent back to the level measuring device by radio.

If the remaining battery life is critical, a warning can be issued on the sensor, for example via an optical signal using an LED 111 in combination with a series resistor 112.

The times, frequency and intervals of the warning messages over the remaining battery life can be parameterized at the factory or via the radio module. It is possible that in addition to the sensor operator, the factory can also be notified so that a new sensor can be provided if necessary. At the same time, the data collected on the sensor side, which is necessary for calculating the remaining battery life, can also be transmitted to the factory anonymously if necessary in order to further refine the algorithms for calculating the remaining battery life of future sensors.

In particular, the remaining life determination device 109, 109a, 109b can be set up to collect various sensor data, calculate a remaining battery life and signal this to the user. Possibilities of signaling are an. LED, a message (email, SMS, . . . ) to a mobile phone or signaling in a user interface on a monitor. It is also possible to have a reverse counter that shows how many measurements are still possible.

The entire measuring device can be integrated in a 101 housing, which is closed and, for example, designed in one piece. In particular, all components may be encapsulated in the housing.

FIG. 3 shows a flow chart of a process according to an embodiment. In step 301, the level measuring device is programmed at the factory so that it can carry out the process steps described above and access the data to be stored at the theory. In step 302, the device is delivered to the customer, who then starts the level measuring device in step 303. In step 304, the corresponding circuit components are awakened from the energy-saving modes and in step 305, the measured data is recorded and evaluated, i.e. the level, limit level or pressure is determined, for example.

In step 306, the battery condition of the measuring device is recorded, for example by measuring the battery voltage or determining the current delivered by the battery in steps 304 and 305. In step 307, data from the other sensors arranged in the measuring device are queried (time, temperature, and in step 308, the minimum value of the remaining battery life is calculated with the data stored at the factory, the current sensor parameterization and the data determined by the internal sensors of the device. In step 309, the measurement data is transmitted via the radio module to a receiver and in step 310, the remaining battery life is transmitted via the radio module to one or more receivers. In step 311, a warning is displayed in the cloud, in the server, at the user and/or directly at the sensor, if necessary, namely if the remaining battery life has fallen below a certain threshold value. In step 312, new parameterization data is received, such as the desired next measurement time. And in step 313, a measurement pause is initiated during which the measuring device enters an energy-saving mode. In step 314, a new measurement cycle is performed, which starts with step 304.

In addition, it should be noted that “comprising” and “having” do not exclude any other elements or steps and the indefinite articles “a” or “an” do not exclude any multiplicity. It should also be noted that features or steps described with reference to one of the above embodiments may also be used in combination with other features or steps of other embodiments described above. Reference signs in the claims are not to be regarded as restrictions.

1. A battery operated level measuring device, comprising;
a battery; and
processing circuitry configured to obtain information from which a minimum value of the remaining battery life is calculable.

2. The battery operated level measuring device according to claim 1, further comprising measurement circuitry, wherein the processing circuitry is further configured to count the measurements performed by the measurement circuitry.

3. The battery operated level measuring device according to claim 1, wherein the processing circuitry is further configured to count the number of measured value display events and/or measured value transmissions to an external receiver.

4. The battery operated level measuring device according to claim 1, wherein the measurement circuitry includes a Coulomb meter configured to measure the amount of charge removed from the battery.

5. The battery operated level measuring device as claimed in claim 4, wherein said Coulomb meter is integrated in a battery voltage control circuit.

6. The battery operated level measuring device according to claim 1, wherein the measurement circuitry includes a battery voltage control circuit configured to measure the voltage of the battery.

7. The battery operated level measuring device according to claim 1, wherein the measurement circuitry includes a temperature sensor configured to measure the temperature of the battery.

8. The battery operated level measuring device according to claim 1, further comprising a real time clock.
wherein the processing is configured to obtain the current date and/or time from the real time clock and compare the current date and/or time with a time stamp of the battery.

9. The battery operated level measuring device according to claim 1, further comprising:
a data memory in which information about the type and capacity of the battery is stored.

10. The battery operated level measuring device according to claim 1, wherein the processing circuitry is further configured to obtain the number of measurements performed by the measurement circuitry, the number of measured value display events and/or measured value transmissions to the external receiver, the amount of charge taken from the battery, the voltage of the battery and/or the current date, the current time and/or the information about the type and capacity of the battery as the obtained information or to take into account the number of measurements performed by the measurement circuitry, the number of measured value display events and/or measured value transmissions to the external receiver, the amount of charge taken from the battery, the voltage of the battery and/or the current date, the current time and/or the information about the type and capacity of the battery in calculating the minimum value of the remaining battery life.

11. The battery operated level measuring device according to claim 1, wherein the battery is fixedly mounted in an irreplaceable manner.

12. The battery operated level measuring device according to claim 1,
whereby the battery operated level measuring device is exclusively battery operated.

13. The battery operated level measuring device according to claim 1, wherein the processing circuitry is further configured to signal a low remaining life to a user.

14. A method for determining a remaining life of a battery of a measuring device, comprising:
obtaining information from which a minimum value of remaining battery life is calculable by processing circuitry of the measuring device; and
calculating the minimum value of the remaining battery life from said information by said processing circuitry or external processing circuitry.

15. A non-transitory computer readable medium having stored thereon a program element which, when executed on a processor of a measuring device, instructs the measuring device to perform a method comprising:
obtaining information from which a minimum value of the remaining battery life is calculable by processing circuitry of the measuring device; and
calculating the minimum value of the remaining battery life from said information by said processing circuitry or external processing circuitry.

16. The battery operated level measuring device according to claim 2, wherein the processing circuitry includes the measurement circuitry.
